(19) United States
(12) Patent Application Publication
(10) Pub. No.: US 2025/0234552 A1
(43) Pub. Date: Jul. 17, 2025

(54) MEMORY DEVICE AND MANUFACTURING METHOD THEREOF

(71) Applicant: MACRONIX INTERNATIONAL CO., LTD., HSINCHU (TW)

(72) Inventors: Po-Hao TSENG, Taichung City (TW); Feng-Min LEE, Hsinchu City (TW)

(21) Appl. No.: 18/672,239

(22) Filed: May 23, 2024

Related U.S. Application Data
(60) Provisional application No. 63/621,130, filed on Jan. 16, 2024.

(51) Int. Cl. H10B 43/30; H10B 43/10; H10B 43/27

(52) U.S. Cl. CPC H10B 43/30; H10B 43/10; H10B 43/27

(57) ABSTRACT

A manufacturing method of a memory device is disclosed herein. The manufacturing method includes: arranging first layers and second layers alternatively along a first direction; etching the first layers and the second layers to form a first hole extending along the first direction; forming a first channel structure at an edge of the first hole; forming a first source structure and a first drain structure inside the first hole; and forming a first charge trap structure surrounding the first channel structure, in which a material of the first layers is different from a material of the second layers.

### CROSS-REFERENCE TO RELATED APPLICATION

This application claims priority to U.S. Provisional Application Ser. No. 63/621,130, filed Jan. 16, 2024, which is herein incorporated by reference in its entirety.

### BACKGROUND

### Technical Field

The present disclosure relates to a memory technique. More particularly, the present disclosure relates to a memory device and a manufacturing method of a memory device.

### Description of Related Art

A semiconductor chip can be formed by a metal oxide semiconductor field effect transistor (MOSFET). However, MOSFET has a higher subthreshold swing, such that the power consumption is higher. Thus, techniques associated with the designing for overcoming the problems described above are important issues in the field.

### SUMMARY

The present disclosure provides a manufacturing method of a memory device. The manufacturing method includes: arranging a plurality of first layers and a plurality of second layers alternatively along a first direction; etching the plurality of first layers and the plurality of second layers to form a first hole extending along the first direction; forming a first channel structure at an edge of the first hole; forming a first source structure and a first drain structure inside the first hole; and forming a first charge trap structure surrounding the first channel structure, in which a material of the plurality of first layers is different from a material of the plurality of second layers.

In some embodiment, the manufacturing method further includes: forming a first intermediate structure at inner edge of the first channel structure; and forming a first isolation structure at inner edge of the first intermediate structure, in which the first isolation structure is located between the first source structure and the first drain structure.

In some embodiment, the manufacturing method further includes: etching the first intermediate structure to form a second hole; when the second hole contacts each of the first channel structure and the first isolation structure, stopping to etch the first intermediate structure; and forming the first source structure in the second hole.

In some embodiment, the manufacturing method further includes: after the first source structure is formed, etching the first intermediate structure to form a third hole; when the third hole contacts each of the first channel structure and the first isolation structure, stopping to etch the first intermediate structure; and forming the first drain structure in the third hole.

In some embodiment, the manufacturing method further includes: etching the plurality of first layers and the plurality of second layers to form a second hole which is separated from the first hole and extends along the first direction; forming a first channel structure at an edge of the second hole; forming a second source structure and a second drain structure inside the second hole; and forming the first charge trap structure surrounding the second channel structure.

In some embodiment, the manufacturing method further includes: removing the plurality of first layers; and after the plurality of first layers are removed, forming a gate structure between the plurality of second layers.

In some embodiment, the plurality of first layers are removed after each of the first source structure and the first drain structure is formed.

In some embodiment, the first charge trap structure is formed before the gate structure is formed, and gate portions of the gate structure are located between charge trap portions of the first charge trap structure.

The present disclosure provides a memory device. The memory device includes a first source structure, a first drain structure, a first channel structure, a first channel structure surrounding each of the first source structure and the first drain structure, a charge trap structure surrounding the first channel structure and a gate structure surrounding the charge trap structure.

In some embodiment, the memory device further includes an isolation structure located between the first source structure and the first drain structure to isolate the first source structure from the first drain structure. Material of the first source structure, material of the first drain structure and material of the isolation structure are different from each other.

In some embodiment, the memory device further includes an oxide layer disposed between a first gate portion of the gate structure and a second gate portion of the gate structure, and surrounding the charge trap structure.

In some embodiment, the memory device further includes a second source structure, a second drain structure a second channel structure separated from the first channel structure, and surrounding each of the second source structure and the second drain structure. The charge trap structure surrounds the second channel structure.

In some embodiment, the first source structure and the first drain structure corresponds to transistors of a first memory column, the second source structure and the second drain structure corresponds to transistors of a second memory column, each of the transistors of the first memory column is configured to receive a first source line signal, and each of the transistors of the second memory column is configured to receive a second source line signal different from the first source line signal.

In some embodiment, a first transistor of the transistors of the first memory column and a second transistor of the transistors of the second memory column share the second gate portion.

In some embodiment, a third transistor of the transistors of the first memory column and a fourth transistor of the transistors of the second memory column share the first gate portion, each of gates of the first transistor and the second transistor is configured to receive a first word line signal, and each of gates of the third transistor and the fourth transistor is configured to receive a second word line signal different from the first word line signal.

The present disclosure provides a memory device. The memory device includes a plurality of memory blocks configured to generate a plurality of bit line signals. Each of the plurality of memory blocks comprising a plurality of memory columns configured to store a plurality of data words, a first memory block of the plurality of memory blocks is configured to compare a search word and the plurality of data words to generate the plurality of bit line signals, each of the plurality of memory columns comprises a plurality of transistors, each of gates of the plurality of transistors is configured to receive a plurality of word line signals carrying the search word, and the gates surrounds sources and drains of the plurality of transistors.

The present disclosure provides a manufacturing method of a memory device. The manufacturing method includes: forming a first channel structure; forming a first isolation structure surrounded by the first channel structure; forming a first source structure and a first drain structure, in which the first isolation structure is located between the first source structure and the first drain structure; forming a charge trap structure surrounding the first channel structure; and forming a gate structure surrounding the charge trap structure.

In some embodiment, the manufacturing method further includes: forming a second channel structure separated from the first channel structure; forming a second isolation structure surrounded by the second channel structure; forming a second source structure and a second drain structure, in which the second isolation structure is located between the second source structure and the second drain structure, and the charge trap structure surrounds the second channel structure.

In some embodiment, the manufacturing method further includes: arranging a plurality of first layers and a plurality of second layers alternatively along a first direction; etching the plurality of first layers and the plurality of second layers to form a first hole extending along the first direction; forming the first channel structure in the first hole; and after the first drain structure is formed, removing the plurality of first layers.

In some embodiment, material of the first isolation structure is same as material of the plurality of first layers.

In some embodiment, the manufacturing method further includes: forming an intermediate structure at inner edge of the first channel structure; and etching the intermediate structure to form a second hole and a third hole separated from each other, in which the first source structure and the first drain structure are formed in the second hole and the third hole, respectively.

It is to be understood that both the foregoing general description and the following detailed description are examples, and are intended to provide further explanation of the disclosure as claimed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a memory system illustrated according to some embodiments of present disclosure.

FIG. 2A to FIG. 2I are schematic diagrams of process steps for manufacturing a memory device illustrated according to some embodiments of present disclosure.

FIG. 2J is a side-view schematic diagram of a process step for manufacturing the memory device illustrated according to some embodiments of present disclosure.

FIG. 2K is a side-view schematic diagram of a process step for manufacturing the memory device illustrated according to some embodiments of present disclosure.

FIG. 2L is a schematic diagram of a process step for manufacturing the memory device illustrated according to some embodiments of present disclosure.

FIG. 2M is a top-view diagram of a part of the memory device illustrated according to some embodiments of present disclosure.

FIG. 3A is a schematic diagram of a relationship between a gate voltage signal applied to the gate structure and the current signal I1 illustrated according to some embodiments of present disclosure.

FIG. 3B is a schematic diagram of various conditions of the transistor formed by the channel structure, the charge trap structure, the source structure and the drain structure in the memory device performing the search operation, illustrated according to some embodiments of present disclosure.

FIG. 4 is a schematic diagram a memory device, illustrated according to some embodiments of present disclosure.

### DETAILED DESCRIPTION

In the present disclosure, when an element is referred to as “connected” or “coupled”, it may mean “electrically connected” or “electrically coupled”. “Connected” or “coupled” can also be used to indicate that two or more components operate or interact with each other. In addition, although the terms “first”, “second”, and the like are used in the present disclosure to describe different elements, the terms are used only to distinguish the elements or operations described in the same technical terms. The use of the term is not intended to be a limitation of the present disclosure.

Unless otherwise defined, all terms (including technical and scientific terms) used in the present disclosure have the same meaning as commonly understood by the ordinary skilled person to which the concept of the present invention belongs. It will be further understood that terms (such as those defined in commonly used dictionaries) should be interpreted as having a meaning consistent with its meaning in the related technology and/or the context of this specification and not it should be interpreted in an idealized or overly formal sense, unless it is clearly defined as such in this article.

The terms used in the present disclosure are only used for the purpose of describing specific embodiments and are not intended to limit the embodiments. As used in the present disclosure, the singular forms “a”, “one” and “the” are also intended to include plural forms, unless the context clearly indicates otherwise. It will be further understood that when used in this specification, the terms “comprises (comprising)” and/or “includes (including)” designate the existence of stated features, steps, operations, elements and/or components, but the existence or addition of one or more other features, steps, operations, elements, components, and/or groups thereof are not excluded.

Hereinafter multiple embodiments of the present disclosure will be disclosed with schema, as clearly stated, the details in many practices it will be explained in the following description. It should be appreciated, however, that the details in these practices is not applied to limit the present disclosure. Also, it is to say, in some embodiments of the present disclosure, the details in these practices are non-essential. In addition, for the sake of simplifying schema, some known usual structures and element in the drawings by a manner of simply illustrating for it.

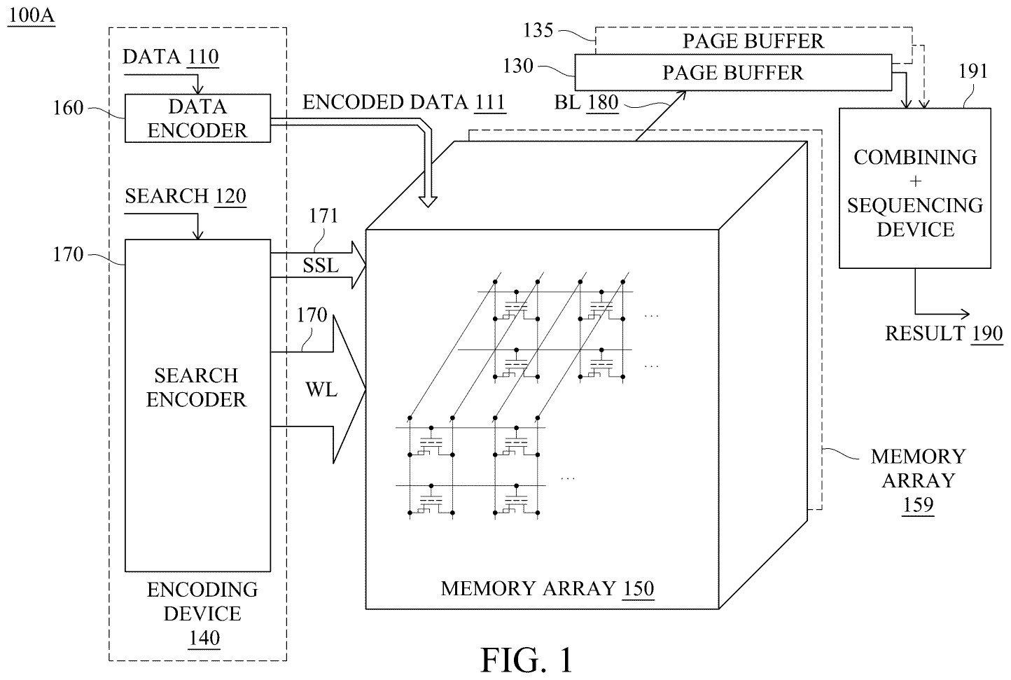

FIG. 1 is a schematic diagram of a memory system 100A illustrated according to some embodiments of present disclosure. In some embodiments, the memory system 100A can be implemented by a three dimensional (3D) tunnel field effect transistor (TFET) in-memory search system. As shown in FIG. 1, the memory system 100A includes an encoding device 140, memory arrays 150, 159, page buffers 130, 135 and combining/sequencing device 191. The encoding device 140 can includes a data encoder 160 and a search encoder 170. The memory array 150 can include multiple TFET arranged in 3D.

In some embodiments, the data encoder 160 is configured receive data signals 110 and generate encoded data signals 111. The search encoder 170 is configured to receive search signals 120 and generate string select line (SSL) signals 171 and word line (WL) signals 172. The memory array 150 is configured to receive the encoded data signals 111, the string select line signals 171 and word line signals 172, and generate bit line (BL) signals 180. The page buffer 130 is configured to receive the bit line signals 180 and output to the combining/sequencing device 191. The combining/sequencing device 191 is configured to process the output of the bit line signals 180 to generate the search results 190.

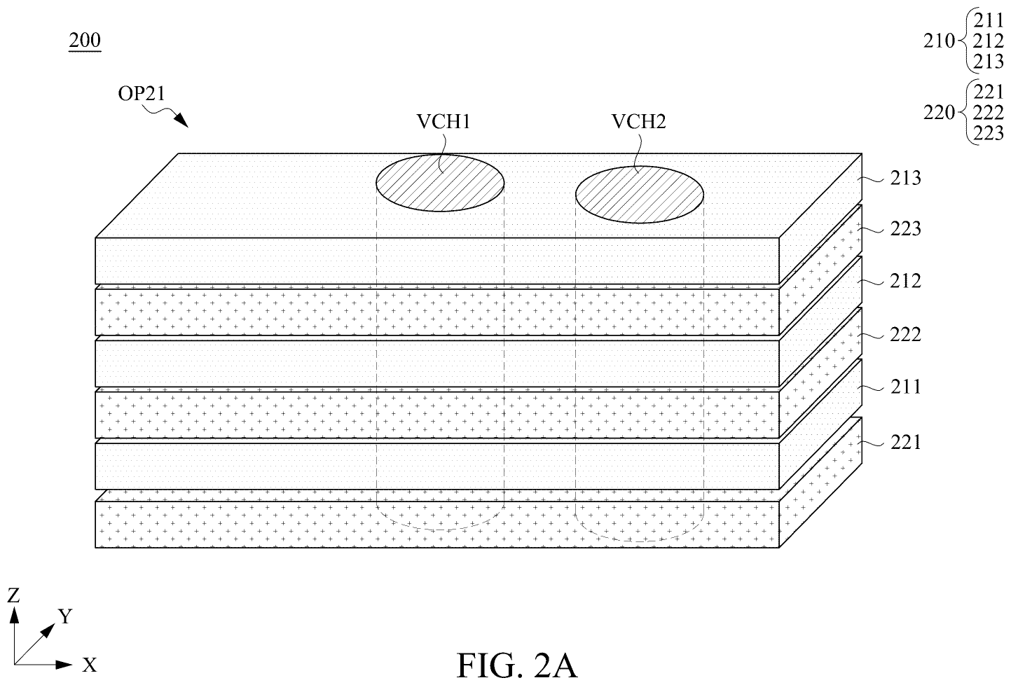

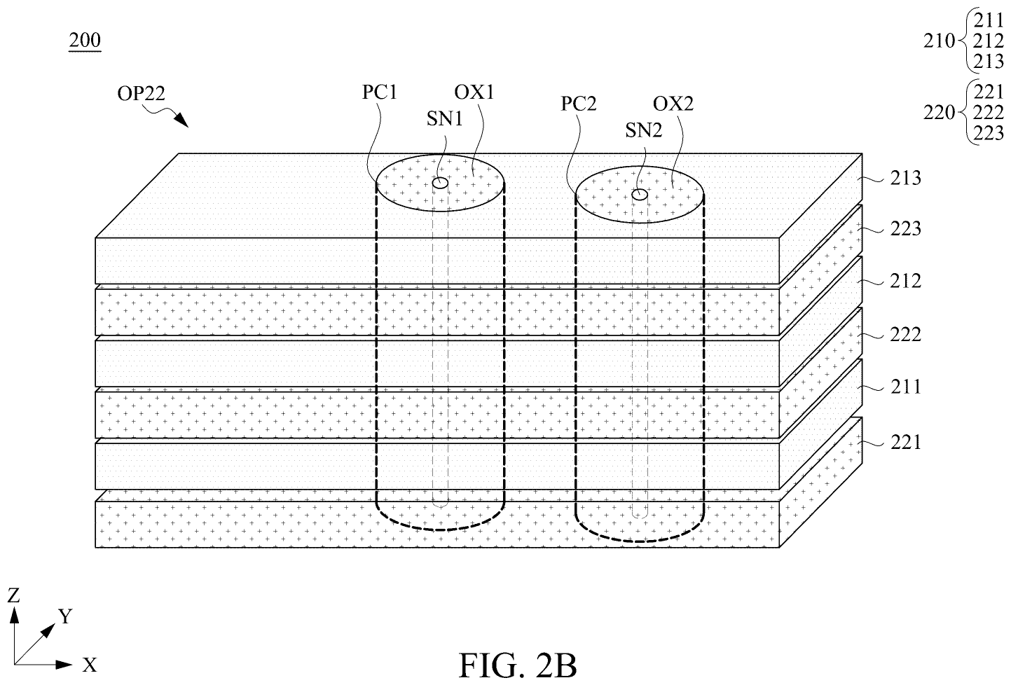

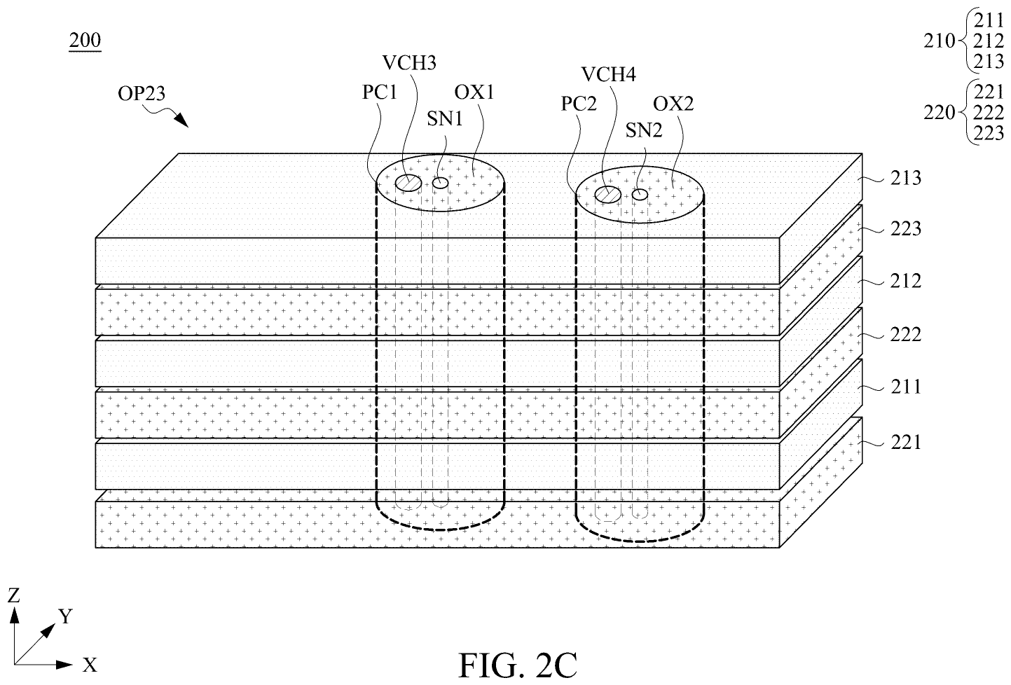

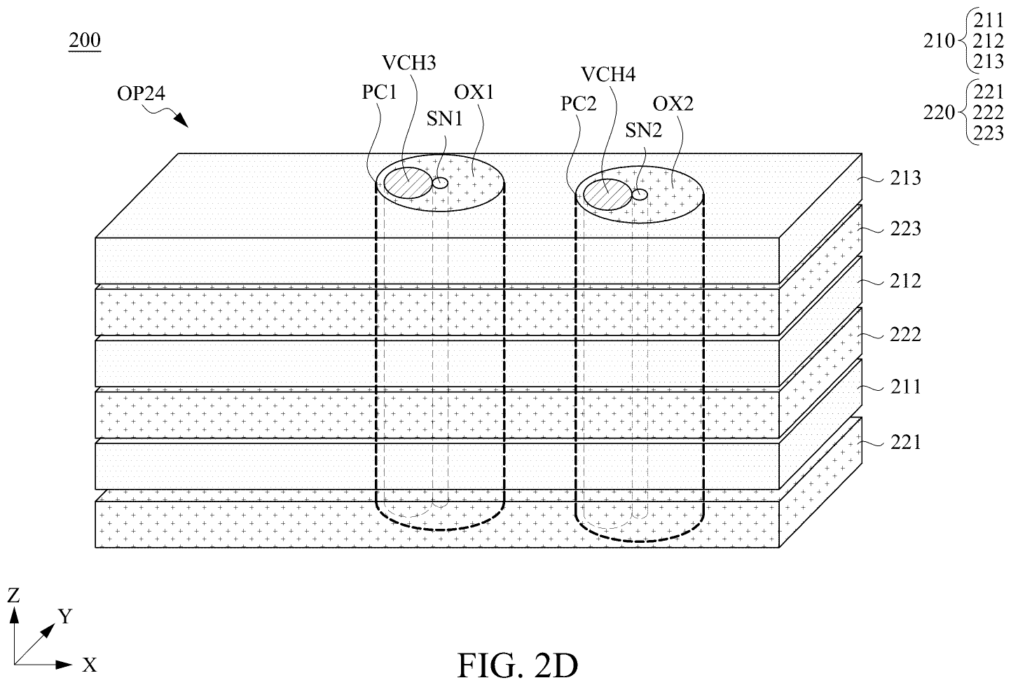

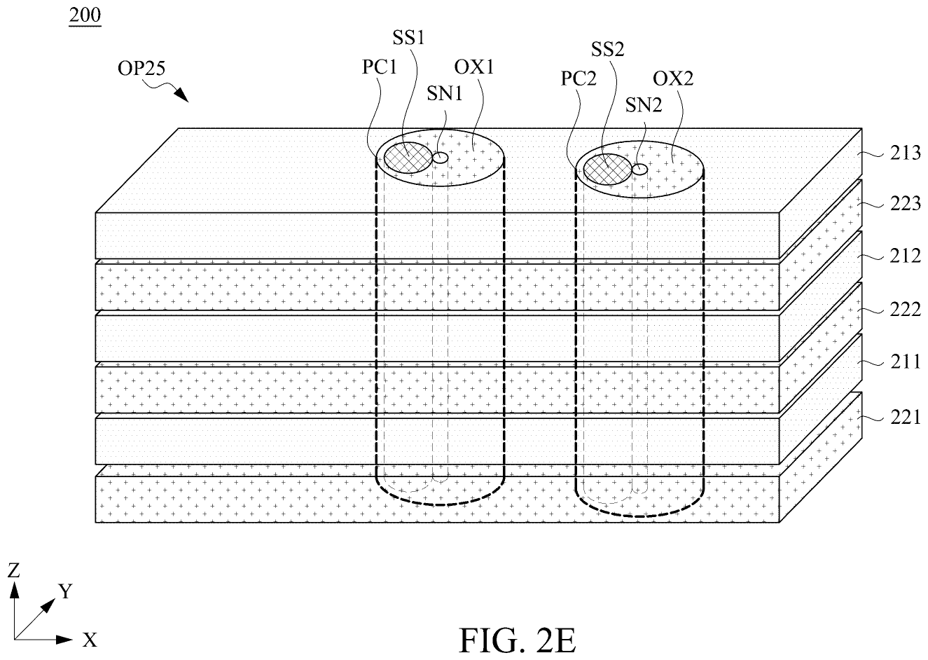

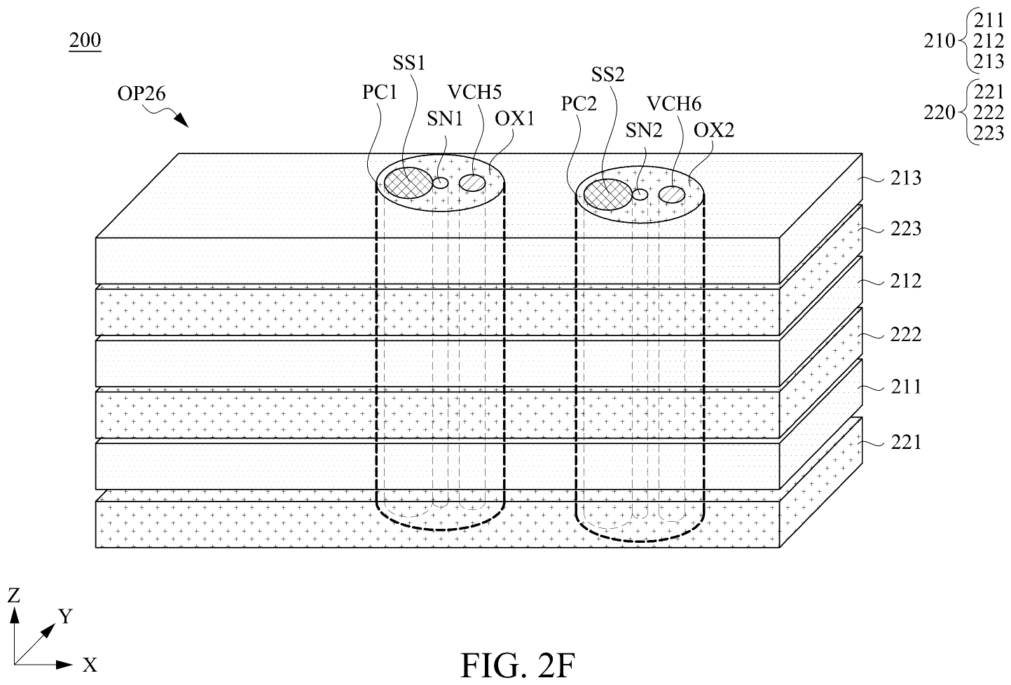

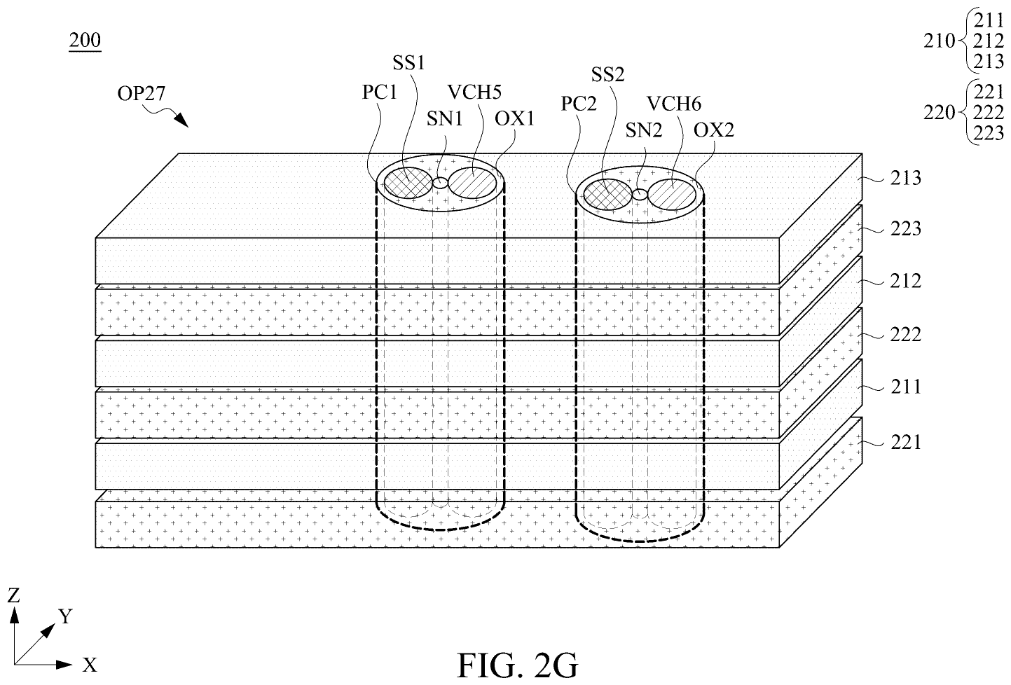

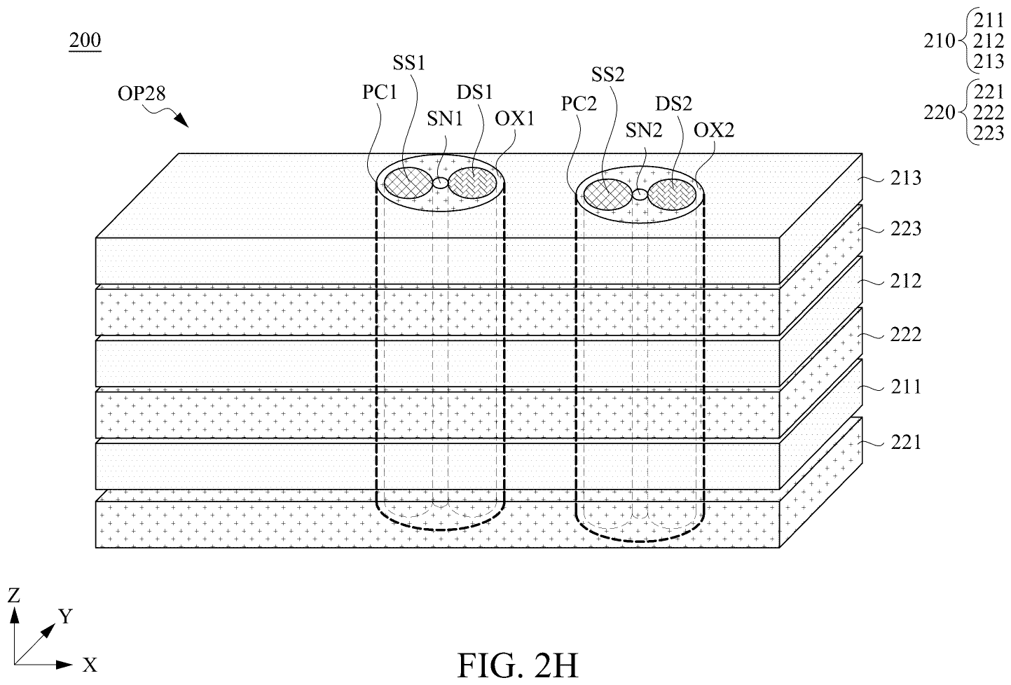

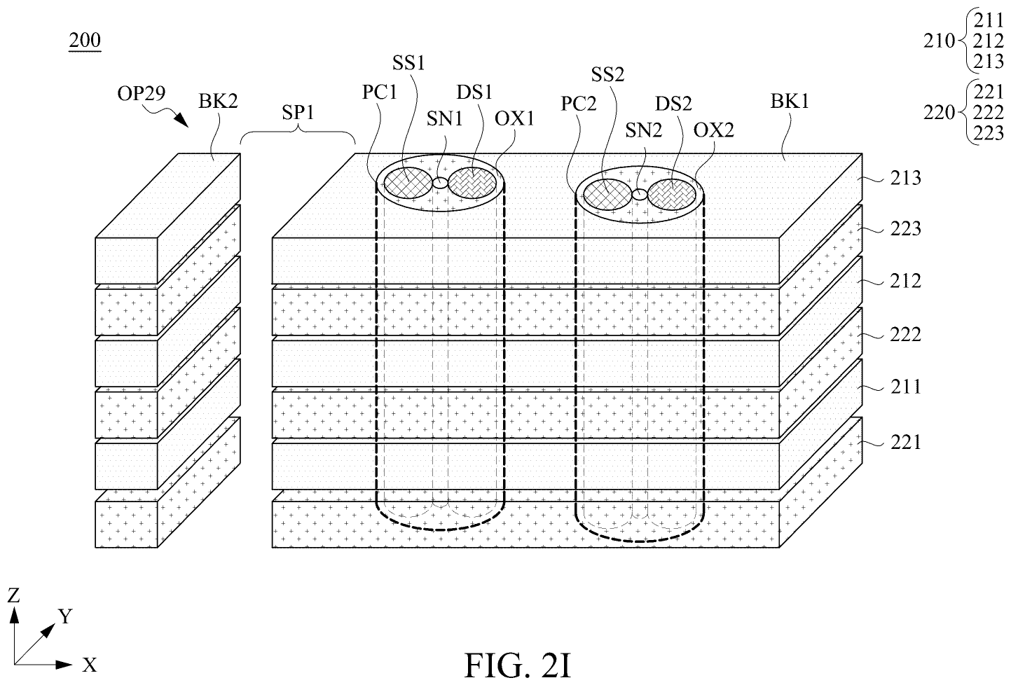

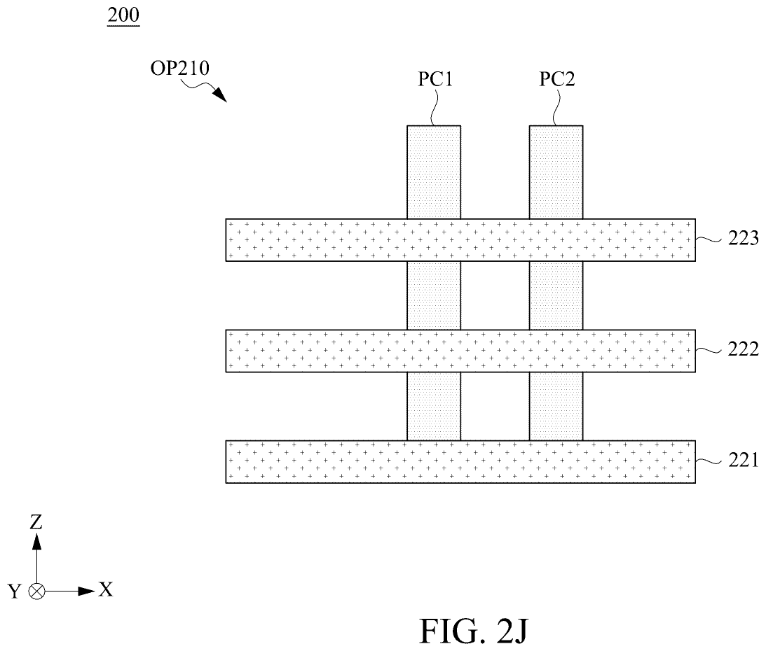

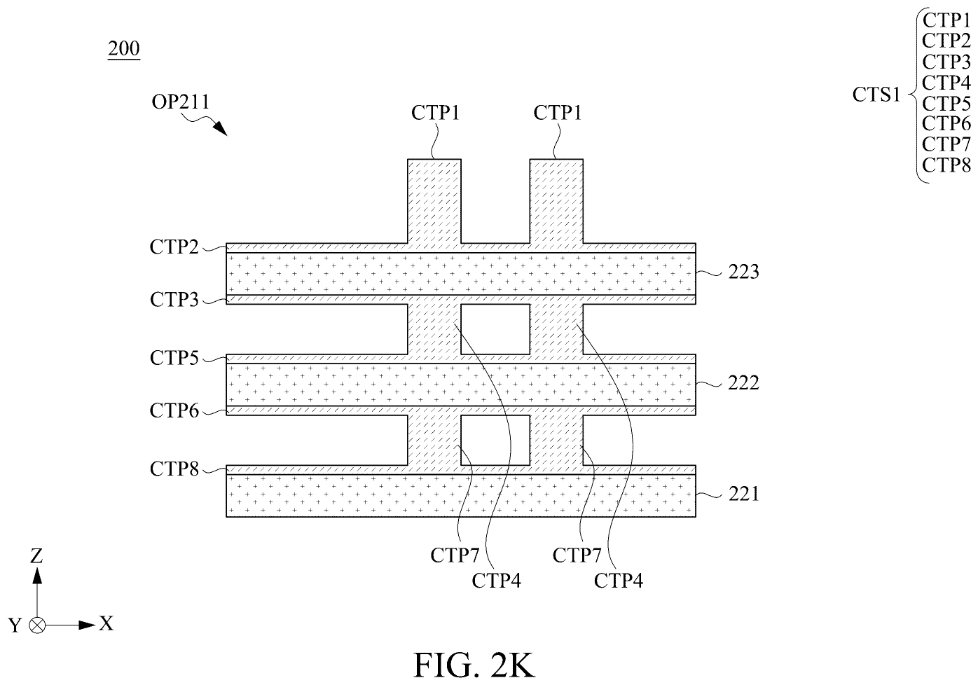

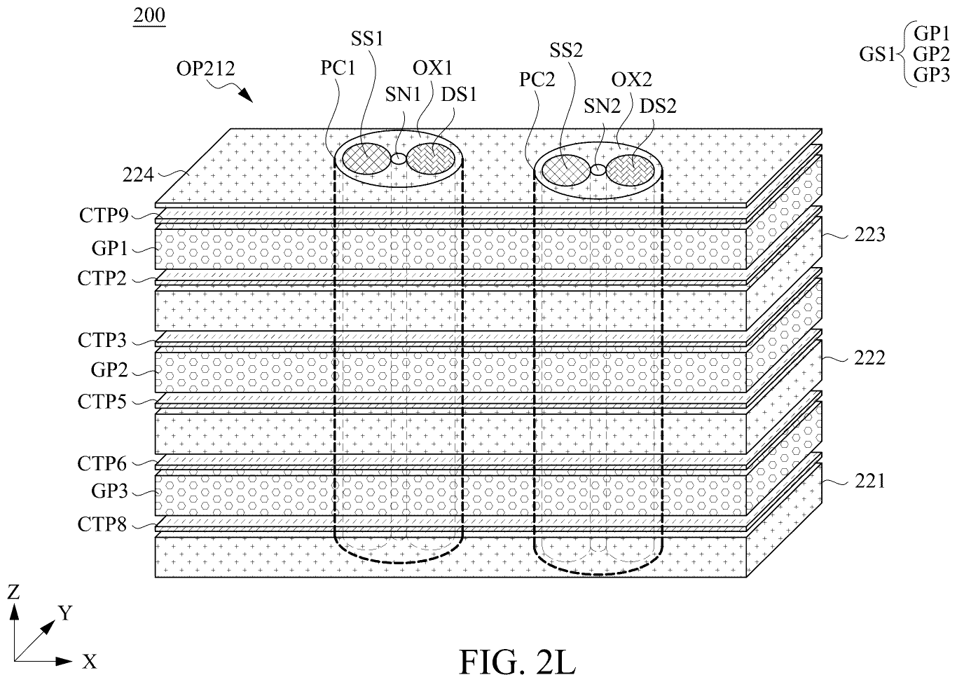

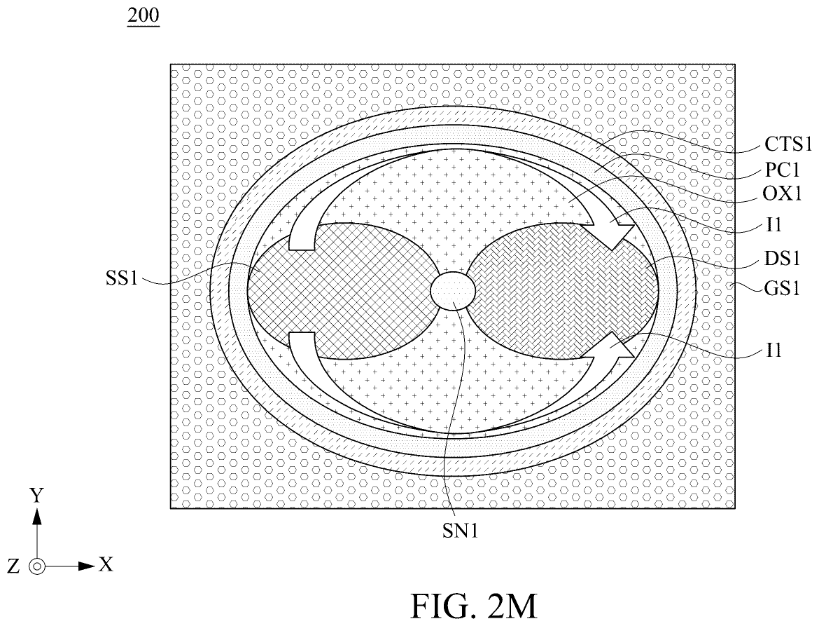

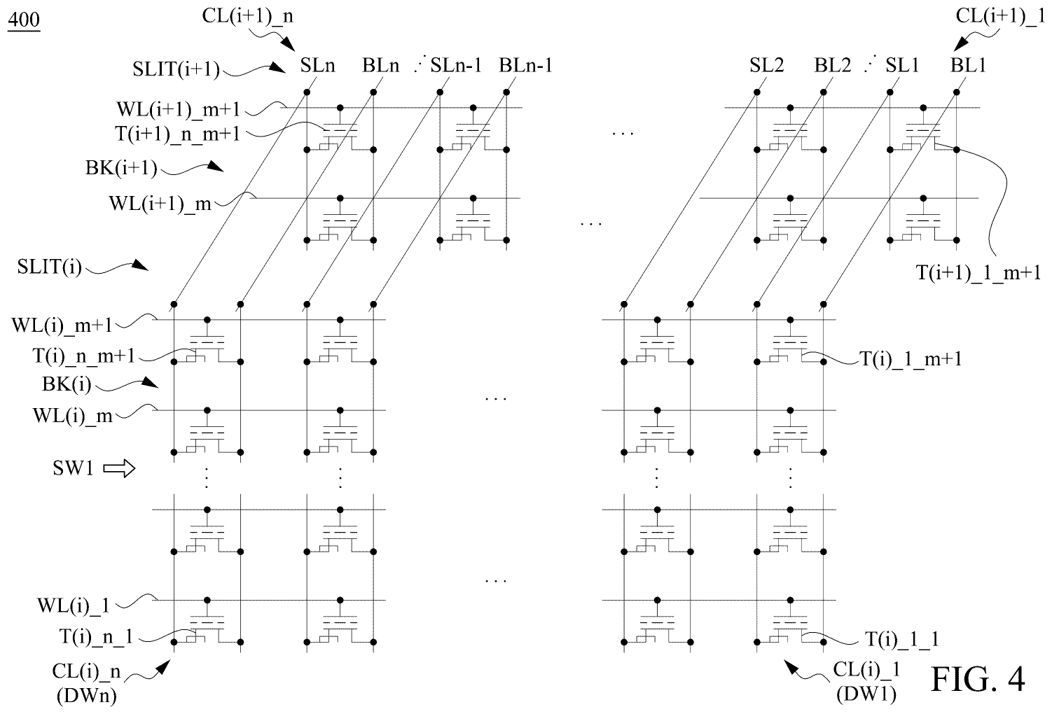

In some embodiments, the process performed by the combining/sequencing device 191 to the bit line signals 180 includes logic processes of AND logic, OR logic or counting, and also may include combining processes of the three logic processes described above. Referring to FIG. 2L and FIG. 4, the combining/sequencing device 191 can receive sense results from the memory devices 200 and/or 400, and controls sequencing (whether serial or parallel) and combines sense results to produce overall search results as the search results 190.

In some embodiments, the memory system 100A can be implemented on a single integrated circuit die, multiple integrated circuits, or be implemented as a component of a system-on-a-chip (SOC). As a specific example, the memory system 100A is implemented on a single integrated circuit die, and can perform searching and combining logic operations in the single integrated circuit die.

FIG. 2A is a schematic diagram of a process step OP21 for manufacturing a memory device 200 illustrated according to some embodiments of present disclosure. Referring FIG. 1 and FIG. 2A, the memory device 200 can be an embodiment of the memory array 150.

As shown in FIG. 2A, the memory device 200 includes multiple nitride layers 210 and multiple oxide layers 220. In the embodiment shown in FIG. 2A, the nitride layers 210 includes three nitride layers 211-213, and the oxide layers 220 includes three oxide layers 221-223. However, the embodiments of present disclosure are not limited to this. In various embodiments, the nitride layers 210 and the oxide layers 220 can have various layer numbers.

In some embodiments, the nitride layers 210 and the oxide layers 220 are arranged alternatively along a Z direction. Alternatively stated, along the Z direction, the oxide layer 221, the nitride layer 211, the oxide layer 222, the nitride layer 212, the oxide layer 223 and the nitride layer 213 are arranged in order. In some embodiments, the stack of the nitride layers 210 and the oxide layers 220 are referred to as oxide nitride stack (ON stack). In some embodiments, material of the nitride layers 210 is silicon nitride. Material of the oxide layers 220 is silicon dioxide.

In some embodiments, a manufacturing device (not shown in the figures) can perform the process step OP21. During the process step OP21, the manufacturing device etches the nitride layers 210 and the oxide layers 220 along the Z direction, to form holes VCH1 and VCH2. In some embodiments, the process step OP21 is referred to as vertical channel hole etching.

As shown in FIG. 2A, the holes VCH1 and VCH2 extend through the nitride layers 210 and the oxide layers 220, and are separated from each other. In some embodiments, each of the holes VCH1 and VCH2 has approximately a cylinder shape.

FIG. 2B is a schematic diagram of a process step OP22 for manufacturing the memory device 200 illustrated according to some embodiments of present disclosure. During the process step OP22, the manufacturing device fills channel material, oxide material and nitride material into the holes VCH1 and VCH2, to form channel structures PC1, PC2, intermediate structures OX1, OX2 and isolation structures SN1, SN2.

Specifically, at first, the manufacturing device forms the channel structure PC1 at inner edge of the hole VCH1, and forms the channel structure PC2 at inner edge of the hole VCH2. Then, the manufacturing device forms the intermediate structure OX1 at inner edge of the channel structure PC1, and forms the intermediate structure OX2 at inner edge of the channel structure PC2. Finally, the manufacturing device forms the isolation structure SN1 at inner edge of the intermediate structure OX1, and forms the isolation structure SN2 at inner edge of the intermediate structure OX2. Alternatively stated, the intermediate structures OX1 and OX2 surrounds the isolation structures SN1 and SN2, respectively, and the channel structures PC1 and PC2 surrounds the intermediate structures OX1 and OX2, respectively.

In some embodiments, material of the channel structures PC1 and PC2 is intrinsic poly-silicon. Material of the intermediate structures OX1 and OX2 is oxide, such as silicon dioxide. Material of the isolation structures SN1 and SN2 is silicon nitride.

FIG. 2C is a schematic diagram of a process step OP23 for manufacturing the memory device 200 illustrated according to some embodiments of present disclosure. During the process step OP23, the manufacturing device performs plug etching to the intermediate structures OX1 and OX2 along the Z direction, to generate holes VCH3 and VCH4.

As shown in FIG. 20, the holes VCH3 and VCH4 extend through the intermediate structures OX1 and OX2, respectively. The hole VCH3 is located between the isolation structure SN1 and the channel structure PC1, and is separated from the isolation structure SN1 and the channel structure PC1. The hole VCH4 is located between the isolation structure SN2 and the channel structure PC2, and is separated from the isolation structure SN2 and the channel structure PC2. In some embodiments, each of the holes VCH3 and VCH4 has approximately a cylinder shape.

FIG. 2D is a schematic diagram of a process step OP24 for manufacturing the memory device 200 illustrated according to some embodiments of present disclosure. During the process step OP24, the manufacturing device performs plug pullback process step to the holes VCH3 and VCH4.

Specifically, the manufacturing device can fill hydrofluoric acid (HF) into the holes VCH3 and VCH4, to etch the intermediate structures OX1 and OX2 from the holes VCH3 and VCH4, such that the size of the holes VCH3 and VCH4 are increased.

Then, when the hole VCH3 contacts each of the inner edge of the channel structure PC1 and the isolation structure SN1, and the hole VCH4 contacts each of the inner edge of the channel structure PC2 and the isolation structure SN2, the process step OP24 stops.

FIG. 2E is a schematic diagram of a process step OP25 for manufacturing the memory device 200 illustrated according to some embodiments of present disclosure. During the process step OP25, the manufacturing device fills source material into the holes VCH3 and VCH4, to form the source structures SS1 and SS2.

In some embodiments, the manufacturing device performs chemical vapor deposition (CVD) and doping simultaneously. Accordingly, the source structures SS1 and SS2 are formed and doped with P-type atoms simultaneously, such that the source structures SS1 and SS2 are formed by P-rich type material. In some embodiments, the source material forming the source structures SS1 and SS2 is P-rich poly silicon.

In some embodiments, after the source material are filled into the holes VCH3 and VCH4, the manufacturing device is further configured to perform chemical-mechanical polishing (CMP), to polish the source structures SS1 and SS2 along the Z direction, such that a height of each of the source structures SS1 and SS2 is same as a height of each of the channel structures PC1, PC2, the intermediate structures OX1 and OX2 and the isolation structures SN1, SN2.

FIG. 2F is a schematic diagram of a process step OP26 for manufacturing the memory device 200 illustrated according to some embodiments of present disclosure. During the process step OP26, the manufacturing device performs plug etching to the intermediate structures OX1 and OX2 along the Z direction, to generate holes VCH5 and VCH6.

As shown in FIG. 2F, the holes VCH5 and VCH6 extend through the intermediate structures OX1 and OX2, respectively. The hole VCH5 is located between the isolation structure SN1 and the channel structure PC1, and is separated from the isolation structure SN1 and the channel structure PC1. The hole VCH6 is located between the isolation structure SN2 and the channel structure PC2, and is separated from the isolation structure SN2 and the channel structure PC2. In some embodiments, each of the holes VCH5 and VCH6 has approximately a cylinder shape.

FIG. 2G is a schematic diagram of a process step OP27 for manufacturing the memory device 200 illustrated according to some embodiments of present disclosure. During the process step OP27, the manufacturing device performs plug pullback process step to the holes VCH5 and VCH6.

Specifically, the manufacturing device can fill hydrofluoric acid (HF) into the holes VCH5 and VCH6, to etch the intermediate structures OX1 and OX2 from the holes VCH5 and VCH6, such that the size of the holes VCH5 and VCH6 are increased.

Then, when the hole VCH5 contacts each of the inner edge of the channel structure PC1 and the isolation structure SN1, and the hole VCH6 contacts each of the inner edge of the channel structure PC2 and the isolation structure SN2, the process step OP27 stops.

FIG. 2H is a schematic diagram of a process step OP28 for manufacturing the memory device 200 illustrated according to some embodiments of present disclosure. During the process step OP28, the manufacturing device fills source material into the holes VCH5 and VCH6, to form the drain structures DS1 and DS2.

In some embodiments, the manufacturing device performs chemical vapor deposition (CVD) and doping simultaneously. Accordingly, the drain structures DS1 and DS2 are formed and doped with N-type atoms simultaneously, such that the drain structures DS1 and DS2 are formed by N-rich type material. In some embodiments, the drain material forming the drain structures DS1 and DS2 is N-rich poly silicon.

In some embodiments, after the drain material are filled into the holes VCH5 and VCH6, the manufacturing device is further configured to perform chemical-mechanical polishing (CMP), to polish the drain structures DS1 and DS2 along the Z direction, such that a height of each of the drain structures DS1 and DS2 is same as a height of each of the channel structures PC1, PC2, the intermediate structures OX1 and OX2 and the isolation structures SN1, SN2.

As shown in FIG. 2H, along the X direction, the source structure SS1 and the drain structure DS1 are located at two opposite sides of the isolation structure SN1, respectively. The source structure SS2 and the drain structure DS2 are located at two opposite sides of the isolation structure SN2, respectively. In some embodiments, the source structures SS1, SS2 and the drain structures DS1 and DS2 have the same size. In some embodiments, the size of the source structures SS1, SS2 and the drain structures DS1 and DS2 is larger than a size of each of the isolation structures SN1 and SN2.

FIG. 2I is a schematic diagram of a process step OP29 for manufacturing the memory device 200 illustrated according to some embodiments of present disclosure. During the process step OP29, the manufacturing device performs slit etching to the memory device 200 to form a separation portion SP1.

As shown in FIG. 2I, the memory device 200 includes blocks BK1 and BK2. Along the X direction, the blocks BK1 and BK2 are separated from each other by the separation portion SP1. In some embodiments, the manufacturing device can form more separation portions to separate the memory device 200 into more blocks.

FIG. 2J is a side-view schematic diagram of a process step OP210 for manufacturing the memory device 200 illustrated according to some embodiments of present disclosure. In FIG. 2J, the Y direction points into the paper. During the process step OP210, the manufacturing device removes the nitride layers 210. At this moment, along the Z direction, the oxide layers 221-223 are separated from each other, and there are no nitride layers 210 between two of the oxide layers 221-223. Along the X direction, the channel structures PC1 and PC2 are separated from each other and there are no nitride layers 210 between the channel structures PC1 and PC2.

FIG. 2K is a side-view schematic diagram of a process step OP211 for manufacturing the memory device 200 illustrated according to some embodiments of present disclosure. In FIG. 2K, the Y direction points into the paper. During the process step OP211, the manufacturing device forms the charge trap structure CTS1 on the surfaces of the oxide layers 221-223 and the channel structures PC1 and PC2.

As shown in FIG. 2K, the charge trap structure CTS1 includes charge trap portions CTP1-CTP8. Along the Z direction, the charge trap portion CTP2 covers an upper surface of the oxide layer 223, the charge trap portion CTP3 covers a lower surface of the oxide layer 223, the charge trap portion CTP5 covers an upper surface of the oxide layer 222, the charge trap portion CTP6 covers a lower surface of the oxide layer 222, and the charge trap portion CTP8 covers an upper surface of the oxide layer 221.

On the other hand, the charge trap portion CTP1 is located above the charge trap portion CTP2, and surrounds the channel structures PC1 and PC2. The charge trap portion CTP4 is located between the charge trap portions CTP3 and CTP5, and surrounds the channel structures PC1 and PC2. The charge trap portion CTP7 is located between the charge trap portions CTP6 and CTP8, and surrounds the channel structures PC1 and PC2.

In some embodiments, the charge trap structure CTS1 can be implemented by oxide-nitride-oxide (ONO) material. In some embodiments, the process step OP211 is referred to as ONO deposition.

FIG. 2L is a schematic diagram of a process step OP212 for manufacturing the memory device 200 illustrated according to some embodiments of present disclosure. During the process step OP212, the manufacturing device forms a gate structure GS1. In the embodiment shown in FIG. 2L, the oxide layers 224 further includes an oxide layer 224, and the charge trap structure CTS1 further includes a charge trap portion CTP9. Along the Z direction, the oxide layer 224 is located above the charge trap portion CTP9.

As shown in FIG. 2L. the gate structure GS1 includes gate portions GP1-GP3. The gate portion GP1 is interposed between the charge trap portions CTP9 and CTP2, and surrounds the charge trap portion CTP1. The gate portion GP2 is interposed between the charge trap portions CTP3 and CTP5, and surrounds the charge trap portion CTP4. The gate portion GP3 is interposed between the charge trap portions CTP6 and CTP8, and surrounds the charge trap portion CTP7. In some embodiments, the gate structure GS1 can be implemented by tungsten (W). In some embodiments, the process step OP212 can be referred to as tungsten gate deposition.

Referring to FIG. 2J to FIG. 2L, during the process steps OP210-OP212, the nitride layers 210 are replaced by the gate structure GS1 and the charge trap structure CTS1. Accordingly, the process steps OP210-OP212 can be referred to as gate replacement process step. In some embodiments, the process steps OP21-OP212 are performed in order.

FIG. 2M is a top-view diagram of a part of the memory device 200 illustrated according to some embodiments of present disclosure. In FIG. 2M, the Z direction point out from the paper.

A shown in FIG. 2M, on the X-Y plane, the gate structure GS1 surrounds the charge trap structure CTS1. The charge trap structure CTS1 surrounds the channel structure PC1. The channel structure PC1 surrounds the intermediate structure OX1, the source structure SS1, the drain structure DS1 and the isolation structure SN1. Along the X direction, the isolation structure SN1 is located between the source structure SS1 and the drain structure DS1, to isolate the source structure SS1 and the drain structure DS1 from each other.

In some embodiments, the gate structure GS1, the source structure SS1 and the drain structure DS1 can operate as gates, sources an drains, respectively, of multiple transistors. Similarly, the gate structure GS2, the source structure SS2 and the drain structure DS2 shown in FIG. 2L can also operate as gates, sources an drains, respectively, of multiple transistors.

In some embodiments, the transistors described above are referred to as three-dimensional (3D) tunnel field effect transistor (TFET). During operations, the memory device 200 generates the current signal I1 according to the voltage level of the gate structure GS1 and the threshold voltage level corresponding to the charge trap structure CTS1. The current signal I1 flows from the source structure SS1 to the drain structure DS1.

In some approaches, a semiconductor chip can be formed by a metal oxide semiconductor field effect transistor (MOSFET). However, MOSFET has a higher subthreshold swing, such that the power consumption is higher.

Compared to above approaches, in the embodiments of present disclosure, the memory device 200 is formed by the source structure SS1 to the drain structure DS1, the source structure SS1 has P type dopant, and the drain structure DS1 has N type dopant, such that the memory device 200 can operate as TFET. TFET has a lower subthreshold swing and lower off current, such that the power consumption is lower.

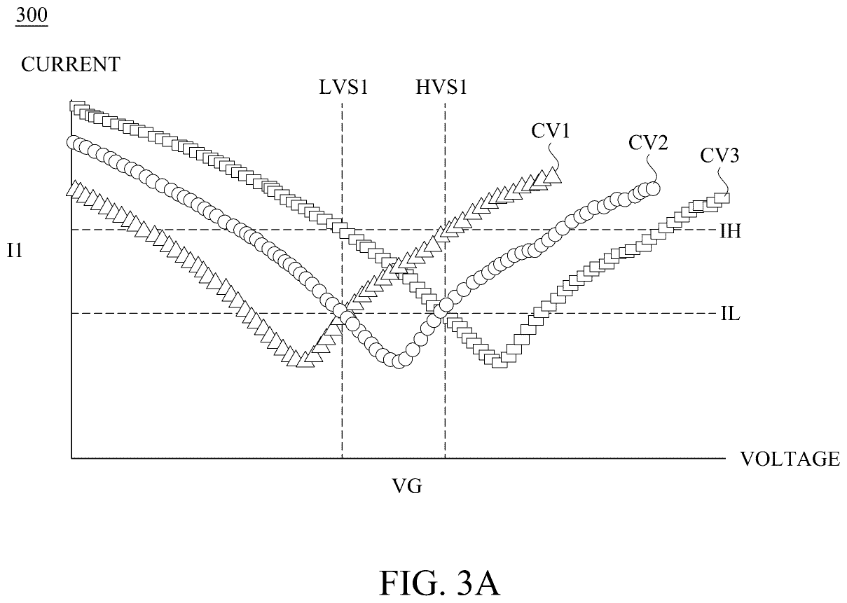

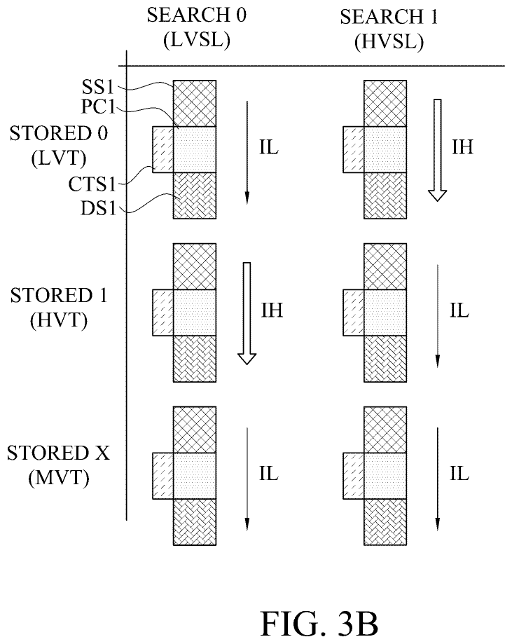

FIG. 3A is a schematic diagram 300 of a relationship between a gate voltage signal VG applied to the gate structure GS1 and the current signal I1 illustrated according to some embodiments of present disclosure. A horizontal axis of the schematic diagram 300 corresponds to voltage levels of the gate voltage signal VG. A vertical axis of the schematic diagram 300 corresponds to current levels of the current signal I1, and is presented in log scale.

As shown in FIG. 3A, the schematic diagram 300 includes curves CV1-CV3. The curves CV1-CV3 corresponds to three states of the transistor which the current signal I1 flows through, respectively. In the state corresponding to the curve CV1, the transistor is configured to store the logic value 0. In the state corresponding to the curve CV2, the transistor is configured to store the logic value X. In some embodiments, the logic value X represents a “don't care” logic value. In the state corresponding to the curve CV3, the transistor is configured to store the logic value 1.

As shown in FIG. 3A, when the gate voltage signal VG has a voltage level LVSL, each of the current signals I1 corresponding to the curves CV1 and CV2 has a current level IL, and the current signal I1 corresponding to the curve CV3 has a current level IH. When the gate voltage signal VG has a voltage level HVSL, each of the current signals I1 corresponding to the curves CV3 and CV2 has the current level IL, and the current signal I1 corresponding to the curve CV1 has the current level IH. In some embodiments, the voltage level HVSL is larger than the voltage level LVSL, and the current level IH is larger than the current level IL.

FIG. 3B is a schematic diagram 300 of various conditions of the transistor formed by the channel structure PC1, the charge trap structure CTS1, the source structure SS1 and the drain structure DS1 in the memory device 200 performing the search operation, illustrated according to some embodiments of present disclosure. During the search operation, the memory device 200 can compare a logic value of a data bit DT1 stored by the transistor and a logic value of a search bit SB1 carried by the gate voltage signal VG, to generate the corresponding current I1. As shown in FIG. 3B, the transistor can operate under six conditions. The six conditions are arranged in two columns and three rows.

In the conditions of the first column, the search bit SB1 has the logic value 0, such that the gate voltage signal VG has the voltage level LVSL. In the conditions of the second column, the search bit SB1 has the logic value 1, such that the gate voltage signal VG has the voltage level HVSL.

In the conditions of the first row, the data bit DT1 has the logic value 0, such that the transistor has a threshold voltage level LVT. In the conditions of the second row, the data bit DT1 has the logic value 1, such that the transistor has a threshold voltage level HVT. In the conditions of the third row, the data bit DT1 has the logic value X, such that the transistor has a threshold voltage level MVT. In some embodiments, the threshold voltage level HVT is larger than the threshold voltage level MVT, and the threshold voltage level MVT is larger than the threshold voltage level LVT.

In some embodiments, a charge quantity in the charge trap structure CTS1 is proportional to the threshold voltage level of the transistor. Alternatively stated, in the conditions of the first row, the charge quantity is the smallest. In the conditions of the second row, the charge quantity is the largest. In the conditions of the third row, the charge quantity is between those of the conditions of the first row and the conditions of the second row.

As shown in FIG. 3B, in the condition of the first column and the second row and the condition of the second column and the first row, in response to the logic values of the data bit DT1 and the search bit SB1 are different, the current signal I1 has the current level IH. In the other four conditions, in response to the logic values of the data bit DT1 and the search bit SB1 are the same, the current signal I1 has the current level IL. It is noted that the logic value X can correspond to the logic value 0, and can also correspond to the logic value 1.

FIG. 4 is a schematic diagram a memory device 400, illustrated according to some embodiments of present disclosure. As shown in FIG. 4, the memory device 400 can includes multiple memory blocks, such as memory blocks BK(i) and BK(i+1), in which i is a positive integer. For brevity, other memory blocks, such as the memory block BK(i−1), are not shown in FIG. 4.

In some embodiments, the memory device 400 further includes slits SLIT(i) and SLIT(i+1). The slit SLIT(i) is configured to separate the memory blocks BK(i) and BK(i+1). The slit SLIT(i+1) is configured to separate the memory blocks BK(i+1) and BK(i+2).

As shown in FIG. 4, the memory block BK(i) includes memory columns CL(i)_1-CL(i)_n, in which n is a positive integer. The memory column CL(i)_1 includes transistors T(i)_1_1-T(i)_1_m+1. The memory column CL(i)_2 includes transistors T(i)_2_1-T(i)_2_m+1, and so on. The memory column CL(i)_n includes transistors T(i)_n_1-T(i)_n_m+1.

Similarly, the memory block BK(i+1) includes memory columns CL(i+1)_1-CL(i+1)_n, in which n is a positive integer. The memory column CL(i+1)_1 includes transistors T(i+1)_1_1-T(i+1)_1_m+1. The memory column CL(i+1)_2 includes transistors T(i+1)_2_1-T(i+1)_2_m+1, and so on. The memory column CL(i+1)_n includes transistors T(i+1)_n_1-T(i+1)_n_m+1.

In some embodiments, each of the gates of the transistors T(i)_1_1-T(i)_n_1 is configured to receive a word line signal WL(i)_1. Each of the gates of the transistors T(i)_1_2-T(i)_n_2 is configured to receive a word line signal WL(i)_2, and so on. Each of the gates of the transistors T(i)_1_m+1-T(i)_n_m+1 is configured to receive a word line signal WL(i)_m+1.

Similarly, each of the gates of the transistors T(i+1)_1_1-T(i+1)_n_1 is configured to receive a word line signal WL(i+1)_1. Each of the gates of the transistors T(i+1)_1_2-T(i+1)_n_2 is configured to receive a word line signal WL(i+1)_2, and so on. Each of the gates of the transistors T(i+1)_1_m+1-T(i+1)_n_m+1 is configured to receive a word line signal WL(i+1)_m+1. Referring to FIG. 4 and FIG. 3A, the word line signals WL(i)_1-WL(i)_m+1 and WL(i+1)_1-WL(i+1)_m+1 are embodiments of the gate voltage signal VG.

In some embodiments, the drains of the transistors T(i)_1_1-T(i)_1_m+1 and T(i+1)_1_1-T(i+1)_1_m+1 are configured to output a bit line signal BL1. The drains of the transistors T(i)_2_1-T(i)_2_m+1 and T(i+1)_2_1-T(i+1)_2_m+1 are configured to output a bit line signal BL2, and so on. The drains of the transistors T(i)_n_1-T(i)_n_m+1 and T(i+1)_n_1-T(i+1)_n_m+1 are configured to output a bit line signal BLn.

In some embodiments, the sources of the transistors T(i)_1_1-T(i)_1_m+1 and T(i+1)_1_1-T(i+1)_1_m+1 are configured to receive a source line signal SL1. The sources of the transistors T(i)_2_1-T(i)_2_m+1 and T(i+1)_2_1-T(i+1)_2_m+1 are configured to receive a source line signal SL2, and so on. The sources of the transistors T(i)_n_1-T(i)_n_m+1 and T(i+1)_n_1-T(i+1)_n_m+1 are configured to receive a source line signal SLn.

In some embodiments, the word line signals WL(i)_1-WL(i)_m+1 are configured to carry a search word SW1. The search word SW1 includes search input bits SIB(1)-SIB(m+1). The word line signals WL(i)_1-WL(i)_m+1 are configured to carry the search input bits SIB(1)-SIB(m+1), respectively.

In some embodiments, the memory columns CL(i)_1-CL(i)_n are configured to store data words DW1-DWn, respectively. It is noted that each transistor of the memory columns CL(i)_1-CL(i)_n is configured to store one corresponding data bit of the data words DW1-DWn.

During the search operation, the memory device 400 is configured to compare the search word SW1 and the data words DW1-DWn, and generate corresponding bit line signals BL1-BLn. When search word SW1 and one of the data words DW1-DWn has a higher similarity, a corresponding one of the bit line signals BL1-BLn has a lower current level. When search word SW1 and one of the data words DW1-DWn has a lower similarity, a corresponding one of the bit line signals BL1-BLn has a higher current level.

Referring to FIG. 4 and FIG. 2L, in some embodiments, the memory device 400 can be implemented by the memory device 200. For example, sources of the transistors in the memory column CL(i)_n correspond to the source structure SS1, and drains of the transistors in the memory column CL(i)_n correspond to the drain structure DS1. Sources of the transistors in the memory column CL(i)_n−1 correspond to the source structure SS2, and drains of the transistors in the memory column CL(i)_n−1 correspond to the drain structure DS1. The gate portion GP3 corresponds to gates of the transistors T(i)_1_1-T(i)_n_1. The gate portion GP2 corresponds to gates of the transistors T(i)_1_2-T(i)_n_2. The gate portion GP1 corresponds to gates of the transistors T(i)_1_3-T(i)_n_3.

Alternatively stated, the transistors in the memory column CL(i)_n share the source structure SS1 and the drain structure DS1. The transistors in the memory column CL(i)_n−1 share the source structure SS2 and the drain structure DS2. The transistors T(i)_1_1-T(i)_n_1 share the gate portion GP3. The transistors T(i)_1_2-T(i)_n_2 share the gate portion GP2. The transistors T(i)_1_3-T(i)_n_3 share the gate portion GP1.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A manufacturing method of a memory device, comprising:
arranging a plurality of first layers and a plurality of second layers alternatively along a first direction;
etching the plurality of first layers and the plurality of second layers to form a first hole extending along the first direction;
forming a first channel structure at an edge of the first hole;
forming a first source structure and a first drain structure inside the first hole; and
forming a first charge trap structure surrounding the first channel structure,
wherein a material of the plurality of first layers is different from a material of the plurality of second layers.

2. The manufacturing method of claim 1, further comprising:
forming a first intermediate structure at inner edge of the first channel structure; and
forming a first isolation structure at inner edge of the first intermediate structure,
wherein the first isolation structure is located between the first source structure and the first drain structure.

3. The manufacturing method of claim 2, further comprising:
etching the first intermediate structure to form a second hole;
when the second hole contacts each of the first channel structure and the first isolation structure, stopping to etch the first intermediate structure; and
forming the first source structure in the second hole.

4. The manufacturing method of claim 3, further comprising:
after the first source structure is formed, etching the first intermediate structure to form a third hole;
when the third hole contacts each of the first channel structure and the first isolation structure, stopping to etch the first intermediate structure; and
forming the first drain structure in the third hole.

5. The manufacturing method of claim 1, further comprising:
etching the plurality of first layers and the plurality of second layers to form a second hole which is separated from the first hole and extends along the first direction;
forming a second channel structure at an edge of the second hole;
forming a second source structure and a second drain structure inside the second hole; and
forming the first charge trap structure surrounding the second channel structure.

6. The manufacturing method of claim 1, further comprising:
removing the plurality of first layers; and
after the plurality of first layers are removed, forming a gate structure between the plurality of second layers.

7. The manufacturing method of claim 6, wherein the plurality of first layers are removed after each of the first source structure and the first drain structure is formed.

8. The manufacturing method of claim 6, wherein the first charge trap structure is formed before the gate structure is formed, and gate portions of the gate structure are located between charge trap portions of the first charge trap structure.

9. A memory device, comprising:
a first source structure;
a first drain structure;
a first channel structure surrounding each of the first source structure and the first drain structure;
a charge trap structure surrounding the first channel structure; and
a gate structure surrounding the charge trap structure.

10. The memory device of claim 9, further comprising:
an isolation structure located between the first source structure and the first drain structure to isolate the first source structure from the first drain structure,
wherein material of the first source structure, material of the first drain structure and material of the isolation structure are different from each other.

11. The memory device of claim 9, further comprising:
an oxide layer disposed between a first gate portion of the gate structure and a second gate portion of the gate structure, and surrounding the charge trap structure.

12. The memory device of claim 11, further comprising:
a second source structure;
a second drain structure; and
a second channel structure separated from the first channel structure, and surrounding each of the second source structure and the second drain structure,
wherein the charge trap structure surrounds the second channel structure.

13. The memory device of claim 12, wherein
the first source structure and the first drain structure corresponds to transistors of a first memory column,
the second source structure and the second drain structure corresponds to transistors of a second memory column,
each of the transistors of the first memory column is configured to receive a first source line signal, and
each of the transistors of the second memory column is configured to receive a second source line signal different from the first source line signal.

14. The memory device of claim 13, wherein a first transistor of the transistors of the first memory column and a second transistor of the transistors of the second memory column share the second gate portion.

15. The memory device of claim 14, wherein a third transistor of the transistors of the first memory column and a fourth transistor of the transistors of the second memory column share the first gate portion,
each of gates of the first transistor and the second transistor is configured to receive a first word line signal, and
each of gates of the third transistor and the fourth transistor is configured to receive a second word line signal different from the first word line signal.

16. A manufacturing method of a memory device, comprising:
forming a first channel structure;
forming a first isolation structure surrounded by the first channel structure;
forming a first source structure and a first drain structure, wherein the first isolation structure is located between the first source structure and the first drain structure;
forming a charge trap structure surrounding the first channel structure; and
forming a gate structure surrounding the charge trap structure.

17. The manufacturing method of claim 16, further comprising:
forming a second channel structure separated from the first channel structure;
forming a second isolation structure surrounded by the second channel structure; and
forming a second source structure and a second drain structure,
wherein the second isolation structure is located between the second source structure and the second drain structure, and
the charge trap structure surrounds the second channel structure.

18. The manufacturing method of claim 16, further comprising:
arranging a plurality of first layers and a plurality of second layers alternatively along a first direction;
etching the plurality of first layers and the plurality of second layers to form a first hole extending along the first direction;
forming the first channel structure in the first hole; and
after the first drain structure is formed, removing the plurality of first layers.

19. The manufacturing method of claim 18, wherein material of the first isolation structure is same as material of the plurality of first layers.

20. The manufacturing method of claim 16, further comprising:
forming an intermediate structure at inner edge of the first channel structure; and
etching the intermediate structure to form a second hole and a third hole separated from each other,
wherein the first source structure and the first drain structure are formed in the second hole and the third hole, respectively.
